(19) United States
(12) Patent Application Publication
(10) Pub. No.: US 2011/0150123 A1
(43) Pub. Date: Jun. 23, 2011

(54) TRANSMITTER, RECEIVER, TRANSMITTING METHOD, AND RECEIVING METHOD FOR COMMUNICATION SYSTEM

(75) Inventors: Jae Hee HAN, Daejeon (KR); Pan Soo Kim, Daejeon (KR); Dae Ig Chang, Daejeon (KR)

(73) Assignee: ELECTRONICS AND TELECOMMUNICATIONS RESEARCH INSTITUTE, Daejeon-city (KR)

(21) Appl. No.: 12/915,469

(22) Filed: Oct. 29, 2010

(30) Foreign Application Priority Data
Dec. 21, 2009 (KR) 10-2009-0127729

(51) Int. Cl. H04L 27/00; H03K 9/00

(52) U.S. Cl. 375/295; 375/316

(57) ABSTRACT

The present invention relates to a transmitting method, a receiving method, a transmitter, and a receiver of a communication system. A transmitting method according to an aspect of the present invention includes generating a burst by scattering a plurality of pilot symbols, and transmitting the burst.

### CROSS-REFERENCE TO RELATED APPLICATIONS

This application claims priority under 35 U.S.C. §119 to Korean Patent Application No. 10-2009-0127729, filed on Dec. 21, 2009, in the Korean Intellectual Property Office, the disclosure of which is incorporated herein by reference in its entirety.

### BACKGROUND OF THE INVENTION

1. Field of the Invention

The present invention relates to scattered pilot technology for efficient carrier frequency synchronization in a communication system based on MF-TDMA.

2. Description of the Related Art

DVB-RCS establishes a network through a communication repeater installed in a satellite for data communication in a MPEG2 format. Satellite communication is generally classified into DVB-RCT, DVB-RCS, etc. RCT (Return Channel via Terrestrial) uses a terrestrial network to achieve a reverse link and RCS (Return Channel via Satellite) achieves a reverse link via a satellite. Main Examples of a method of using a terrestrial network includes a method of using PSTN and a method of using Cable and ADSL, and RCS performs direct transmission/reception with a satellite at the position of a subscriber.

Environment of a receiving side in satellite communication has the limitation to power and an antenna size. At the same time, in most of the latest communication standards, it is required that an antenna size be reduced and operation be possible even in a low SNR environment to improve power efficiency. However, a bust structure in DVB-RCS which is a related art has an inserted preamble and remarkably low carrier frequency estimation accuracy in low SNR environment. Therefore, a current DVB-RCS burst structure using a preamble is inadequate to frame structures for the next-generation DVB-RCS standards.

In a burst structure in the DVB-RCS standard based on MF-TDMA according to the related art, there exist four kinds of bursts which includes TRF (Traffic) bursts for information transmission shown in FIGS. 1 and 2, an ACQ (Acquisition) burst for course synchronization shown in FIG. 3, a SYNC (Synchronization) burst for periodic message synchronization shown in FIG. 4, and a CSC (Common Signal Channel) burst for initial connection synchronization shown in FIG. 5. The TRF bursts are divided into an ATM burst shown in FIG. 1 and an MPEG burst shown in FIG. 2. The frame lengths of the individual bursts shown in FIGS. 1, 2, 4, and 5 are defined as shown in Table 1.

TABLE 1

| | |
|---|---|
| TRF ATM burst | ${L}_{ATM} = {L}_{pre} + \frac{n \times 53}{c}$ |
| TRF MPEG burst | ${L}_{MPEG} = {L}_{pre} + \frac{n \times 188}{c}$ |
| SYNC burst | ${L}_{SYNC} = {L}_{pre} + \frac{12}{c}$ |
| CSC burst | ${L}_{CSC} = {L}_{pre} + \frac{16}{c}$ |

Here, Lₚᵣₑ represents the length of a preamble, c represents a code rate, n represents the number of ATM cells or MPEG blocks, and the length of a burst is expressed in bytes.

A pilot symbol is used for preamble detection and phase and frequency synchronization. The phase and frequency synchronization is generally divided into coarse frequency synchronization and fine frequency synchronization. The coarse frequency synchronization uses the correlation between a received signal and a preamble. In the coarse frequency synchronization, an estimation limit according to SNR is determined by the Cramer-Rao bound. In a case of using a preamble, a burst has a structure as shown in FIG. 6.

When a preamble is used, in the coarse frequency synchronization, an estimation limit according to SNR is determined by the Cramer-Rao bound as expressed in following Equation 1.

$${σ}_{δ F} = \frac{1}{2 π} \sqrt{\frac{6}{{L}_{pre} \times ( {L}_{pre}^{2} - 1 ) \times SNR}} \qquad [ Equation 1 ]$$

In Equation 1, Lₚᵣₑ represents the length of a preamble.

When a preamble is used, the Cramer-Rao bound according to the value of Lₚᵣₑ is shown in FIG. 7. As shown in FIG. 7, when a preamble is used, as the length Lₚᵣₑ of the preamble increases, the Cramer-Rao bound becomes lower, and as SNR becomes low, the Cramer-Rao bound becomes higher.

### SUMMARY OF THE INVENTION

In order to solve the above-mentioned problem, it is an object of the present invention to create a burst structure adequate to the next-generation DVB-RCS standards, to improve the accuracy of carrier frequency estimation in a low SNR environment, to make an operation using a small antenna possible, and to improve power efficiency.

The object of the present invention is not limited to the above-mentioned objects but other objects will be apparent to those skilled in the art from the following description.

According to an aspect of the present invention, it is provided a transmitting method of a DVB-RCS (Digital Video Broadcasting-Return Channel via Satellite) system including: generating a burst by scattering a plurality of pilot symbols; and transmitting the burst.

According to another aspect of the present invention, it is provided a receiving method of a DVB-RCS (Digital Video Broadcasting-Return Channel via Satellite) system including: receiving a burst having a plurality of pilot symbols scattered; and extracting the plurality of pilot symbols from the burst and performing synchronization.

According to a further aspect of the present invention, it is provided a transmitter of a DVB-RCS (Digital Video Broadcasting-Return Channel via Satellite) system including: a burst generating unit configured to generate a burst by scattering a plurality of pilot symbols; and a transmitting unit configured to transmit the burst.

According to a still further aspect of the present invention, it is provided a receiver of a DVB-RCS (Digital Video Broadcasting-Return Channel via Satellite) system including: a receiving unit configured to receive a burst having a plurality of pilot symbols scattered; and a synchronizing unit configured to extract the plurality of pilot symbols from the burst and perform synchronization.

The details of embodiments are included in the specification and drawings.

According to embodiments of the present invention, it is possible to solve the problem in the related art that the accuracy of carrier frequency estimation in a low SNR environment is remarkably low.

### BRIEF DESCRIPTION OF THE DRAWINGS

FIGS. 1 to 6 are conceptual diagrams illustrating examples of a burst structure in a general DVB-RCS standard according to the related art;

FIG. 7 is a graph showing the Cramer-Rao bound according to the length of a preamble in the burst structure of FIG. 6;

FIG. 8 is a view illustrating a configuration of a communication system having a transmitter and a receiver according to an embodiment of the present invention;

FIGS. 9 to 12 are conceptual diagrams illustrating examples of the structure of a burst which the transmitter of FIG. 8 transmits;

FIGS. 13 to 15 are diagrams illustrating examples of conditions and results of a performance test on a burst structure transmitted by a transmitter according to an embodiment of the present invention;

FIG. 16 is a block diagram illustrating a transmitter of a communication system according to another embodiment of the present invention; and

FIG. 17 is a block diagram illustrating a receiver of a communication system according to another embodiment of the present invention.

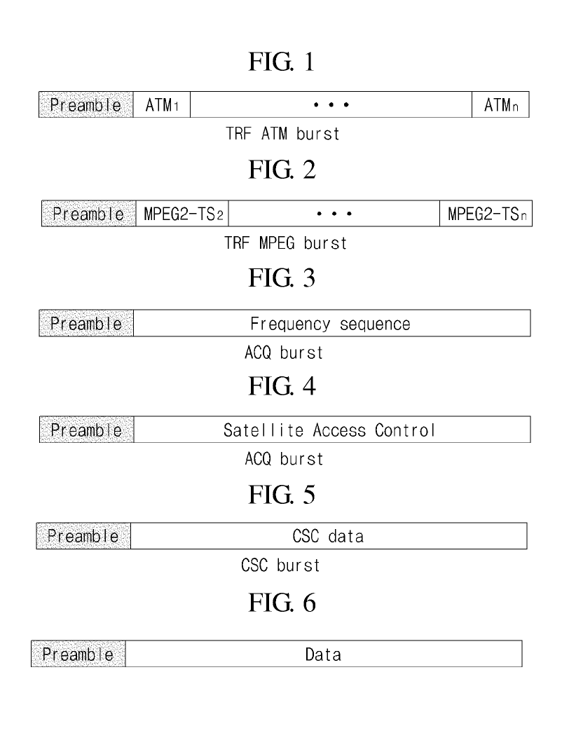

### DETAILED DESCRIPTION OF THE PREFERRED EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein. Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures. It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.). The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

A transmitter, a transmitting method, a receiver, and a receiving method for a communication system according to embodiments of the present invention will be described. A transmitter, a transmitting method, a receiver, and a receiving method for a communication system described below may be applied to a satellite communication system, such as VSAT (Very Small Aperture Terminal) and DVB-RCS, as well as a general communication system.

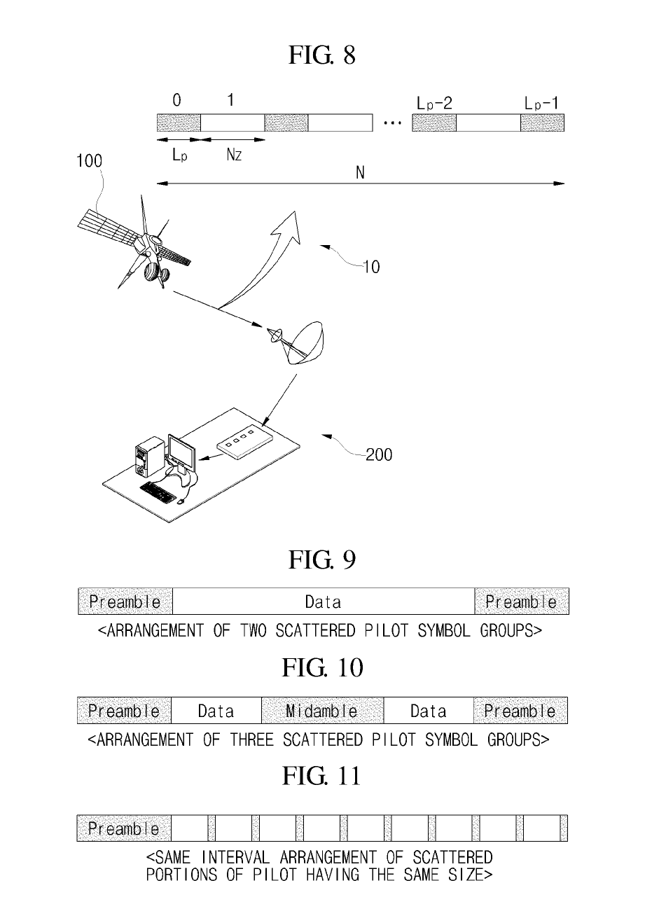

A transmitter, a transmitting method, a receiver, and a receiving method for a communication system according to embodiments of the present invention will be described with reference to FIGS. 8 to 12. FIG. 8 is a view illustrating a configuration of a communication system. FIGS. 9 to 12 are conceptual diagrams illustrating examples of the structure of a burst which a transmitter of FIG. 8 transmits. FIGS. 13 to 15 are diagrams illustrating examples of conditions and results of a performance test on a burst structure transmitted by a transmitter according to an embodiment of the present invention.

A transmitter 100 according to an embodiment of the present invention generates a burst by scattering a plurality of pilot symbols to 0 to Lₚ₋₁, as shown in FIG. 8, and transmits the burst. In FIG. 8, Nₚ represents the length of a pilot (or the number of pilot symbols), N, represents the length of data, and N represents the length of the whole burst (the number of whole symbols). If such a burst in which a pilot is scattered is transmitted, it is possible to improve the accuracy of carrier frequency estimation in a receiver 200.

Since there is a difference in the phase and frequency synchronization performance between the transmitter 100 and the receiver 200 according to how the transmitter 100 disposes scattered pilots, and adding a pilot may cause overhead of data, it is preferable to improve the phase and frequency synchronization performance and minimize overhead of data. Therefore, it is possible to determine optimal number and optimal positions of scattered pilots through performance evaluation. A transmitter and a transmitting method according to specific embodiments of the present invention will be described below with reference to FIGS. 9 to 12.

As shown in FIG. 9, a transmitter 100 according to an embodiment may scatter pilot symbols in a preamble and a postamble of a burst. Data may be disposed between the preamble and the postamble.

As shown in FIG. 10, a transmitter 100 according to another embodiment may dispose scatter pilot symbols in a preamble, a midamble, and a postamble of a burst. That is, the transmitter 100 may divides a number of pilot symbols into three groups, dispose the groups in a burst, and dispose data between the groups.

As shown in FIG. 11, a transmitter 100 according to another embodiment may dispose a number of pilot symbols after a preamble of a burst. In this case, the transmitter 100 may dispose the pilot symbols at regular intervals and dispose data between the pilot symbols. Alternatively, the transmitter 100 may dispose the pilot symbols at intervals having a specific pattern or at arbitrary intervals and dispose data between the pilot symbols.

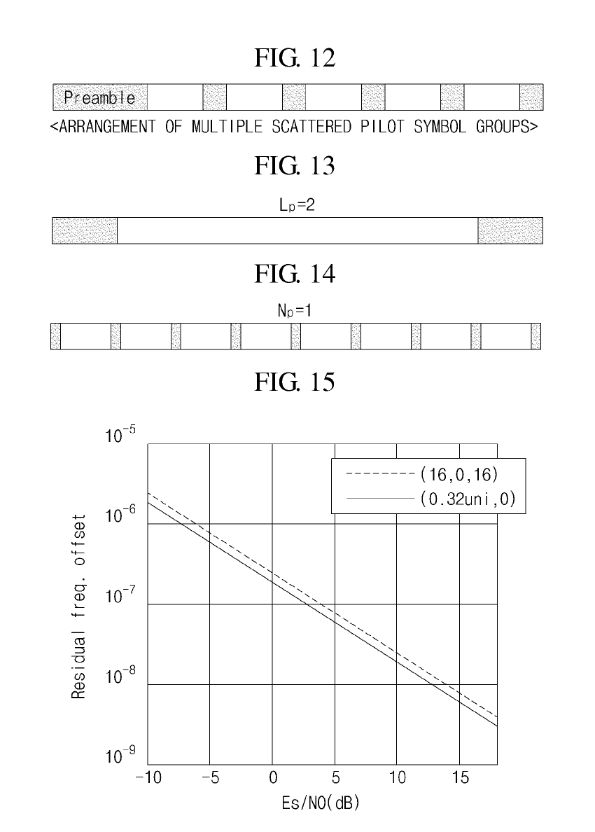

As shown in FIG. 12, a transmitter 100 according to a still further embodiment may divide pilot symbols into a number of groups having a fixed size and dispose the groups after a preamble of a burst. In this case, the transmitter 100 may dispose the groups at regular intervals. Alternatively, the transmitter 100 may dispose the groups at intervals having a specific pattern or at arbitrary intervals and dispose data between the groups.

According to the above-mentioned embodiments, it is possible to improve the accuracy of carrier frequency estimation in the receiver 200 and to improve phase and frequency synchronization performance between the transmitter 100 and the receiver 200.

The results of a performance test on some of the above-mentioned embodiments will be described below with reference to FIGS. 13 to 15.

First, if a number of pilot symbols are divided into two groups (Lₚ=2) and the groups are positioned in a preamble and a postamble of a burst, respectively, as shown in FIG. 13, the Cramer-Rao bound can be expressed as Equation 2.

$${σ}_{δ F} = \frac{3}{2 π \times {E}_{s} / {N}_{0}} \frac{1}{2 {N}_{p} ( 3 {N}_{z}^{2} + 6 {N}_{p} {N}_{z} + 4 {N}_{p}^{2} - 1 )} \qquad [ Equation 2 ]$$

Here, Nₚ represents the length of a pilot and N, represents the length of data.

If pilot symbols are uniformly scattered in a burst as shown in FIG. 14, the Cramer-Rao bound of the uniformly scattered burst can be expressed as Equation 3.

$${σ}_{δ F} = \frac{3}{2 π \times {E}_{s} / {N}_{0}} \frac{1}{{( {N}_{z} + 1 )}^{2} {L}_{p} ( {L}_{p}^{2} - 1 )} \qquad [ Equation 3 ]$$

Therefore, when the number of pilot symbols is 32, a format as shown in FIG. 13 is expressed as (16, 0, 16), and a format as shown in FIG. 14 is expressed as (0, 32uni, 0), the Cramer-Rao bounds for the individual formats are expressed as graphs in FIG. 15.

(16, 0, 16) of FIG. 15 is computed when the lengths Nₚ of the preamble and the postamble are 16 symbols and the length of data, N_{z}, is 64 symbols, and (0, 32uni, 0) is computed when the length of data, N_{z}, is 4 symbols and the number of scattered pilots Lp is 32. The length N of whole burst is common as 160 symbols.

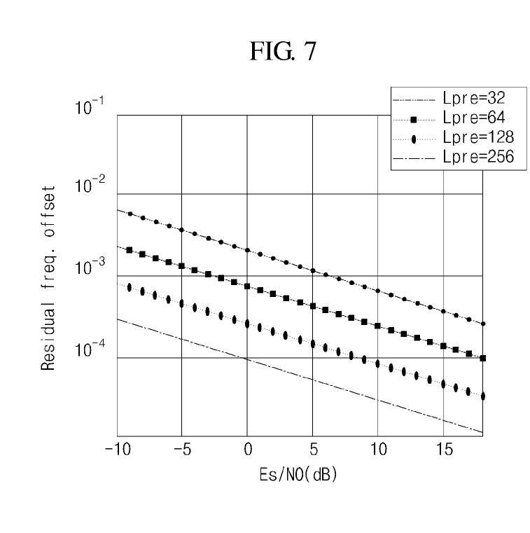

If comparing FIG. 15 with FIG. 7, it can be seen that the accuracy of carrier frequency estimation is improved when pilot symbols are scattered according to the embodiments of the present invention.

Meanwhile, in the above-mentioned scattered pilot techniques, the length of pilot symbols, the number of scattered pilot groups, the size of data, and the like influence the phase and frequency synchronization performance. Also, since overhead according to pilot insertion reduces a data rate and data throughput, the scattered pilot techniques can be applied considering a trade-off therebetween. Therefore, the transmitter 100 may generate any one burst of the burst structures shown in FIGS. 9 to 12 considering a data rate and throughput and transmits the burst. Alternatively, the transmitter 100 may generate a burst having a number of scattered pilot symbols and transmit the burst. In addition, the transmitter 100 may transmit information on how pilot symbols are scattered to the receiver 200. For example, the transmitter 100 may insert information on the arrangement of scattered pilot symbols to the burst and transmit the burst. The transmitter 100 may generate and transmit a burst according to a protocol employed for communication between the transmitter 100 and the receiver 200.

The receiver 200 may extract the pilot symbols from the transmitted burst according to the information on the arrangement of scattered pilot symbols in the burst, and estimate the carrier frequency or perform synchronization. For example, the information on the arrangement of scattered pilot symbols may exist in a preamble in the burst. Alternatively, the information on the arrangement of scattered pilot symbols may be transmitted to the receiver 200 as a separate signal. The receiver 200 may obtain information on the arrangement of scattered pilot symbols according to various other conditions.

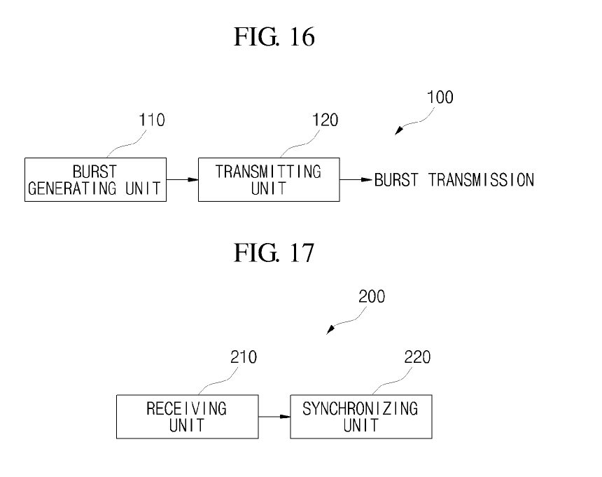

A transmitter and a receiver of a communication system according to other embodiments of the present invention will be described below in detail with reference to FIGS. 16 and 17. FIG. 16 is a block diagram illustrating a transmitter of a communication system according to another embodiment of the present invention, and FIG. 17 is a block diagram illustrating a receiver of a communication system according to another embodiment of the present invention.

Referring to FIG. 16, a transmitter 100 according to another embodiment includes a burst generating unit 110 and a transmitting unit 120.

The burst generating unit 110 generates a burst by scattering a number of pilot symbols. For example, the burst generating unit 110 may generate a burst having any one of the burst structures shown in FIGS. 9 to 12 or another burst structure. The transmitting unit 120 transmits the burst.

Here, the burst generating unit 110 may insert information on the arrangement of scattered pilot symbols to the burst. For example, the burst generating unit 110 may insert the information of the arrangement of scattered pilot symbols to a preamble of the burst.

Referring to FIG. 17, a receiver 200 according to another embodiment includes a receiving unit 210 and a synchronizing unit 220.

The receiving unit 210 receives the burst transmitted from the transmitter 100 of FIG. 15. The received burst has a number of scattered pilot symbols.

The synchronizing unit 220 may extract a number of pilot symbols from the received burst and estimate the carrier frequency or perform synchronization. At this time, the synchronizing unit 220 may extract a number of pilot symbols from the burst according to the information on the arrangement of scattered pilot symbols inserted in the burst. The synchronizing unit 220 may obtain the information on the arrangement of scattered pilot symbols from the preamble of the burst. Alternatively, the synchronizing unit 220 may obtain the information on the arrangement of scattered pilot symbols according to a protocol employed for communication between the transmitter 100 and the receiver 200. The synchronizing unit 220 may also obtain the information on the arrangement of scattered pilot symbols according to various other conditions.

Although the embodiments of the present invention have been described above with reference to the accompanying drawings, they are used in a generic and descriptive sense only and not for purposes of limitation. It will be apparent to those skilled in the art that modifications and variations can be made in the present invention without deviating from the spirit or scope of the invention.

What is claimed is:

1. A transmitting method of a VSAT (Very Small Aperture Terminal) system comprising:
generating a burst by scattering a plurality of pilot symbols; and
transmitting the burst.

2. The method according to claim 1, wherein:
the generating of the burst comprises inserting information on the arrangement of scattered pilot symbols to the burst.

3. The method according to claim 2, wherein:
in the inserting, the information on the arrangement of scattered pilot symbols is inserted to a preamble of the burst.

4. The method according to claim 1, wherein:
the generating of the burst comprises dividing the plurality of pilot symbols into two groups and scattering the groups in the burst.

5. The method according to claim 4, wherein:
the generating of the burst comprises:
dividing the plurality of pilot symbols into two groups; and
disposing one of the two groups in a preamble of the burst and the other of the two groups in a postamble of the burst.

6. The method according to claim 4, wherein:
in the generating of the burst, the two groups are disposed in a predetermined pattern having an interval between the two groups.

7. The method according to claim 1, wherein:
in the generating of the burst, the plurality of pilot symbols are scattered at predetermined intervals.

8. A receiving method of a VSAT (Very Small Aperture Terminal) system comprising:
receiving a burst having a plurality of pilot symbols scattered; and
extracting the plurality of pilot symbols from the burst and performing synchronization.

9. The method according to claim 8, wherein:
the performing of the synchronization comprises extracting the plurality of pilot symbols from the burst according to information on the arrangement of scattered pilot symbols.

10. The method according to claim 9, wherein:
the information on the arrangement of scattered pilot symbols is in a preamble of the burst.

11. The method according to claim 8, wherein:
the burst has at least two scattered groups including the plurality of pilot symbols.

12. The method according to claim 8, wherein:
the plurality of pilot symbols in the burst have a predetermined pattern having intervals between the plurality of pilot symbols.

13. A transmitter of a VSAT (Very Small Aperture Terminal) system comprising:
a burst generating unit configured to generate a burst by scattering a plurality of pilot symbols; and
a transmitting unit configured to transmit the burst.

14. The transmitter according to claim 13, wherein:
the burst generating unit inserts information on the arrangement of scattered pilot symbols to the burst.

15. The transmitter according to claim 13, wherein:
the burst generating unit divides the plurality of pilot symbols into at least two groups and scatters the at least two groups into the burst.

16. The transmitter according to claim 13, wherein:
the burst generating unit disposes the plurality of pilot symbols at intervals.

17. A receiver of a VSAT (Very Small Aperture Terminal) system comprising:
a receiving unit configured to receive a burst having a plurality of pilot symbols scattered; and
a synchronizing unit configured to extract the plurality of pilot symbols from the burst and perform synchronization.

18. The receiver according to claim 17, wherein:
the synchronizing unit extracts the plurality of pilot symbols from the burst according to information on the arrangement of scattered pilot symbols.

19. The receiver according to claim 18, wherein:
the information on the arrangement of scattered pilot symbols is in a preamble of the burst.

20. The receiver according to claim 17, wherein:
the information on the arrangement of scattered pilot symbols is extracted according to a protocol employed for communication with a transmitter having transmitted the burst.
